(19) United States
(12) Patent Application Publication
(10) Pub. No.: US 2024/0411223 A1
(43) Pub. Date: Dec. 12, 2024

(54) METHOD FOR PROCESSING DC MARKS FOR REPAIRING LITHOGRAPHY MASKS

(71) Applicant: Carl Zeiss SMT GmbH, Oberkochen (DE)

(72) Inventors: Jens Oster, Ober-Ramstadt (DE); Bartholomaeus Szafranek, Ober-Ramstadt (DE); Marc Hanefeld, Frankfurt am Main (DE)

(21) Appl. No.: 18/735,341

(22) Filed: Jun. 6, 2024

(30) Foreign Application Priority Data
Jun. 9, 2023 (DE) 102023205392.6

(51) Int. Cl. G03F 1/80; G03F 1/42; G03F 1/74

(52) U.S. Cl. CPC G03F 1/80; G03F 1/42; G03F 1/74

(57) ABSTRACT

The disclosure relates to a method for processing a lithography object. The method comprises using a particle beam and an etching gas to process a marking in order to reduce the volume of the marking, the marking having been deposited on the object and remaining on the object. The invention also relates to a corresponding computer program and a corresponding device.

### CROSS-REFERENCE TO RELATED APPLICATION

This application claims priority to the German patent application no. 10 2023 205 392.6 entitled “Verfahren zum Bearbeiten von DC-Marken für die Reparatur von Lithographie-Masken” and filed with the German Patent and Trademark Office on Jun. 9, 2023, the entire contents of which are incorporated herein by reference.

### TECHNICAL FIELD

The present invention relates to a processing of a marking of an object, e.g. a lithography object, using a particle beam, and to corresponding methods, a corresponding computer program and a corresponding device.

### BACKGROUND

In the semiconductor industry, increasingly smaller structures are produced on a wafer in order to ensure an increase in integration density. Among the methods used here for the production of the structures are lithography methods which image these structures onto the wafer. By way of example, the lithographic methods may comprise, e.g., photolithography, UV lithography, DUV lithography, EUV lithography, x-ray lithography, nanoimprint lithography, etc. In the process, lithography usually makes use of masks (e.g. photomasks, exposure masks, reticles, stamps in the case of nanoimprint lithography, etc.), which comprise a pattern for imaging the desired structures onto a wafer, for example.

As the integration density increases, so do the demands in respect of the mask production (e.g. as a result of the accompanying reduction in the structure dimensions on the mask or as a result of the greater material requirements in lithography). Thus, mask production processes are becoming ever more complex, time-consuming and expensive. Mask flaws (e.g. defects) cannot always be avoided in the process.

Thus, it may be necessary to precisely process a mask in a (predefined) work region, for example in order to rectify or repair mask flaws on a mask. For example, this may be implemented by way of a particle beam-based processing procedure, in which a particle beam is used to process the mask. The particle beam-based processing procedure may comprise, e.g. a particle beam-induced deposition and/or etching. The particle beam-based processing procedure may also comprise an image of the mask being recorded by way of the particle beam.

It may be necessary to resort to markings in order to be able to perform particle beam-based processing of a mask in a defined manner. For example, the markings might be (local) reference markings which, e.g. are raster-scanned for the purpose of (drift) correction and/or monitoring of the processing procedure by the particle beam. In this case, it may be conventional to deposit the markings on the mask in order to be able to carry out defined processing at any desired sites on the mask.

What may happen in the process is that a deposited marking can be used as intended for particle beam-based processing but subsequently itself represents a bothersome element of the mask. For example, a marking deposited on the mask may cause an optical error during a lithographic method (e.g. an infringement of an optical specification). Thus, the marking itself may correspond to a defect on the mask.

Known approaches are usually based on removing the markings without residue following the processing procedure in order to avoid an optical error.

However, this approach cannot (always) be applied to all lithography objects as mask technology advances. For example, a procedure for completely removing a marking may e.g. lead to an impairment of the lithography object.

The present invention is therefore based on the general aspect of providing improved or alternative options for processing lithography objects.

### SUMMARY

This general aspect is at least partly achieved by the various aspects of the present invention.

A first aspect of the invention relates to a method of processing a lithography object, comprising: using a particle beam and an etching gas to process a marking in order to reduce the volume of the marking, the marking having been deposited on the object and remaining on the object.

The lithography object (as described herein) may comprise, e.g. a mask for a lithographic method. For example, the object may comprise an EUV mask for EUV lithography. For example, the EUV mask may comprise an absorbing and/or phase-shifting EUV mask. However, it is also conceivable that the object comprises a mask for any other lithographic method. For example, the object may comprise a mask for DUV lithography, UV lithography, x-ray lithography, nanoimprint lithography.

In an example, the lithography object may also comprise a mask blank. In the lithographic industry, mask blanks are a known starting material for a mask. For example, the mask blank may not comprise any imaging structures like the mask itself but may comprise the layer material thereof.

For example, the marking may have been deposited as a reference structure for correcting a particle beam for processing (e.g. repairing) the object. The marking may comprise, e.g. a reference structure for a drift correction of the particle beam.

In this respect, it should be mentioned that lithography objects may comprise, e.g. electrically insulating samples. Raster-scanning of the object using charged particles (e.g. electrons from an electron beam, ions from an ion beam) may therefore cause electrostatic charging of the object. This charging may inadvertently deflect the particle beam from the intended point of incidence. This effect is referred to as, e.g. drift of a particle beam, with other mechanisms also being able to influence this. For example, the particle beam may also be influenced by a thermal drift. For example, the particle beam may also be influenced by (mechanical) vibrations of one or more components. For example, the vibrations of the object, of an object mount, of a particle beam optical unit and/or of a particle beam deflection unit (e.g. a column) and/or any vibration of the particle beam device may (inadvertently) influence the particle beam. In order nevertheless to enable defined processing of the object, a marking deposited on the object can be used as a reference structure. During processing, the marking can be raster-scanned in order to determine or track the position thereof. The particle beam can be corrected on the basis thereof, in order to ensure defined processing at a desired site on the object. For example, the processing may comprise a particle beam-induced etching and/or deposition, or an image recording by the particle beam.

However, on account of its geometric dimensions, a marking deposited on the object may cause an optical error of the object during lithography. For example, the marking may be designed from a geometrical point of view such that the optical properties of the object are interfered with locally. As a result, a critical dimension in an aerial image of the object (e.g. during lithography and/or during an examination in a piece of inspection equipment) may be infringed, e.g. in a region of the deposited marking.

For example, the optical error might arise if the dimensions of the marking are of the order of the structure dimensions of the lithography object. Thus, it might e.g. be necessary for a marking to necessarily have a specific minimum width and/or minimum height in order to be able to be used as a functional reference structure during a drift correction (e.g. for contrast purposes when identifying the marking in an image). Hence, raster-scanning of the marking and the determination of the position thereof can be reliably ensured, for example. If the marking is of the order of the structure dimension, then the marking may exert an optical influence during lithography. For example, the marking may have an absorbent and/or phase-shifting effect (like a structure on the mask) and consequently cause an optical error. This effect becomes ever more critical with decreasing structure dimensions of the lithography object.

For example, it is known that photolithography masks of the 32 nm process node may have a structure dimension (e.g. a line width) of approximately 130 nm. The latter may be of a similar order to known (drift correction) markings, whose dimensions may lie between 50 and 100 nm, for example. Therefore, the markings in this example may cause unwanted effects. It is known practice to remove these (bothersome) markings without residue (e.g. by way of etching).

However, this approach might not always be able to be used or might not always be advantageous as lithography technology continues to develop. Firstly, the lithography object may be over-etched (i.e. over-processed) for a certain duration during a complete removal of the marking, in order to ensure a complete (e.g. essentially residue-free) removal of the marking material. However, this may increase the risk of the object being attacked and/or damaged in the process.

Over-etching may comprise a procedure in which the object is exposed to an etching component for a comparatively long period of time, at least in the region of the marking. For example, this can ensure that all material of the marking is removed in full or is only (still) present in traces. An attack on and/or damage to the structures of the object cannot always be precluded in the process since the over-etching may also influence the material of the structures on the object. For previous comparatively wide structure dimensions (e.g. greater than 130 nm) and optically less complex lithography methods, such over-etching need not always have had a critical effect. For example, the structure material of such broad structures might be attacked as a result of over-etching (e.g. slight initial etching of mask structures). However, in terms of percentage this may make up a relatively small proportion on account of the broad structure dimensions, and so the risk of causing an optical error of the object in the region of the marking might be small.

However, as technology develops, the dimensions of e.g. imaging structures of lithography objects may become much smaller, for example less than 100 nm, 80 nm, 70 nm and/or less than 60 nm. For example, this may be the case for EUV lithography objects (e.g. for absorbing and/or phase-shifting masks for EUV lithography and/or for masks for high NA EUV lithography). For example, structure widths of EUV masks have in the meantime reached the order of 60 nm, with future trends possibly being directed towards even more delicate (e.g. narrower) structure dimensions. Over-etching markings on objects with smaller structure dimensions (e.g. less than 100 nm) may increase the risk of the structures on the object being able to be attacked and/or influenced much more easily than comparatively larger structures. For example, in the case of such narrower structures, over-etching may cause an attack on the structure material (e.g. a slight initial etching of mask structures) which in terms of percentage makes up a greater proportion on account of the narrower structure dimensions. Thus, the risk of causing an optical error of the object in the region of the marking may be elevated.

Further, it should also be noted that the requirements on the properties of the lithography object materials are becoming increasingly complex since the lithographic methods are becoming increasingly complex from an optical point of view. For example, there are increasingly higher optical requirements on the absorbing and/or phase-shifting properties of masks (or mask blanks). Lithography objects are, e.g. increasingly designed for more complex optical exposures, within which e.g. there is an inclined exposure (also referred to as an oblique illumination) and/or a defined phase-shifting property of the object is desired. For example, ever more complex lithographic methods also increase the requirements in respect of the reliability of the real and/or imaginary refractive index of the mask structures.

Over-etching of a marking may represent a comparatively long exposure of the object to an etching component, whereby it is conceivable that the complex optical properties of the lithography object might be influenced in a bothersome manner.

To fulfil the complex properties, discussions are furthermore increasingly directed to the use of novel materials or material combinations for lithography objects (and the structures thereof). For example, this may lead to a suitably high etching selectivity for the removal of the marking vis-à-vis the object materials not always being able to be ensured. Thus, removing the marking (e.g. by over-etching) may attack the object structures and induce errors in substantially amplified fashion.

Further, over-etching during the complete removal represents a lengthened time component since, e.g. the removal of the marking is only complete once the assumption can be made that (substantially) no residue of the marking is present anymore. However, a long or unnecessary processing duration is not advantageous when processing lithography objects within the scope of semiconductor industry mass production. Instead, procedures are usually designed to save time, for example to enable high throughput, a cost reduction and/or a simplification of the technical complexity.

Thus, the known over-etching and complete removal of a marking does not always represent an optimal solution.

By contrast, the concept of the invention lies in reducing the volume of the deposited marking, with the marking remaining on the object post-processing. Thus, the volume of the marking can be reduced without said marking being removed in full. For example, the volume might be reduced to such an extent that it can be assessed using a scanning electron microscope post-processing. For example, the volume can thus be reduced to an extent where it is visible in a scanning electron microscope image. By contrast, in the case of a complete removal of the marking for example, a marking material could no longer be identified in the scanning electron microscope image.

For example, the first aspect thus relates to a method of processing a lithography object, comprising: using a particle beam and an etching gas to process a marking in order to reduce the volume of the marking, the marking having been deposited on the object and remaining on the object post-processing. In other words, the method may comprise stopping the particle beam and the etching gas, and thus ending the processing at a point in time at which the marking is still present such that the marking remains on the object after the processing has ended.

The approach of the invention may allow the ever-more complex lithography objects to be spared during the processing of an object marking. For example, the marking may be processed according to the method of the first aspect after its functional use (e.g. as drift correction marks for a particle beam). The approach according to the invention can enable a shorter processing time of the marking. Consequently, it is possible to avoid the lithography object being exposed to an etching component for an unnecessarily long period of time.

Reducing the processing time can minimize the risk of negative effects being induced on the structures and/or object materials during the removal. Interfering effects on the optical properties of the object can thus be minimized. As described herein, technical developments may increasingly lead to smaller structure dimensions and/or more complex materials for lithography objects. The method described herein allows this development to be taken into account and offers a more sparing processing procedure which minimizes the risk of impairing optical properties of (increasingly more complex) lithography objects. According to the invention, the lithography object can thus be processed with a lower risk than in the case of the complete removal of the markings.

Further, reducing the processing time may represent a significant time advantage within the scope of mass production. Thus, any process time reduction may be very important in semiconductor industry mass production. As described herein, the method of the first aspect can be implemented following a repair of the object (e.g. a mask repair). It may be conventional for mask repairs to be implemented in industrial mass production with a comparatively high throughput (e.g. in shift operation) since critical mask defects may occur regularly within semiconductor manufacturing (especially in the case of complex lithographic methods). Any time saved during the removal of markings may (overall) represent a huge advantage for a semiconductor factory (e.g. increase in throughput and/or significant cost reduction).

Further, material can also be saved as a result of the invention since less etching gas needs to be used. In particular, this can be based on the fact that there is no over-etching but a targeted initial etching of the marking with a comparatively short duration (in comparison with over-etching). In industrial mass production, etching gas savings may (overall) make up a significant factor and e.g. represent a substantial reduction of costs.

The aforementioned risks and/or disadvantages of a complete removal of the marking can thus be reduced.

In an example, the volume (of the marking) can be reduced such that the processed marking causes no deviation with regards to a predetermined specification during lithography.

One concept of the invention can, e.g. be interpreted as reducing the volume of the marking to at least such an extent that the marking cannot develop a technically disadvantageous effect during lithography. The predetermined specification may be defined for, e.g. an optical image of the object in a reference plane (e.g. an aerial image of a mask). For example, the predetermined specification may comprise a critical dimension in the optical image (e.g. a distance between characteristic lines in an aerial image of the mask, as known in the industrial sector). The predetermined specification may also be defined for, e.g. a resist image, with the resist image being created by way of optical imaging of the object. For example, a substrate (e.g. a wafer) with a developable resist layer may have been exposed and developed over the object. For example, the resist layer may be referred to as a wafer print in industry. For example, the predetermined specification may comprise a critical dimension in the resist image (e.g. a distance between characteristic lines in the resist image of the mask, as known in the industrial sector). For example, the predetermined specification may also be defined (analogously) for an etching, with the etching e.g. possibly corresponding to an etching of the resist image.

Figuratively speaking, the invention can be interpreted as the marking being removed from the optical image of the lithography object but not being physically removed from the object itself. Thus, the marking is removed (only) optically, with the result that an optical specification of the object is not infringed.

Firstly, according to the invention, it is thus possible to manage without unnecessarily long processing of the marking. At the same time, the method can be used in such a way that the marking no longer has a negative influence within the scope of the lithography.

However, the advantages of the invention can also be accompanied by more extensive preparatory measures for the method according to the first aspect. For example, the volume to which the marking must be reduced so that there is no deviation from the predetermined specification can be established experimentally. For example, a field experiment with different processing times (e.g. different etching times) can be used to establish the processing time for the marking with the particle beam and the etching gas after which there is no deviation from the predetermined specification.

In an example, the volume of the marking can be reduced from a first volume to a second (predetermined target) volume. The first volume may correspond to the volume of the marking which the latter had prior to the method of the first aspect being carried out. Thus, the first volume may correspond to the volume of the marking which the latter had prior to the marking being processed by the particle beam and the etching gas. For example, the volume could correspond to an original volume of the marking, which the latter had after the deposition. For example, the first volume of the marking might also deviate from the original volume of the marking. For example, it is conceivable that the marking is raster-scanned by the particle beam for certain purposes following the deposition, and this caused a change in the original volume of the marking. For example, the marking may have been raster-scanned for the purpose of processing the object (e.g. a mask repair), wherein in comparison with the original volume, the volume of the marking may have been increased due to deposition processes or decreased by etching processes.

The second volume may correspond to the volume which the marking has following the method of the first aspect. Thus, the second volume is a volume which the marking has following the marking being processed in accordance with the first aspect. The second volume is therefore smaller than the first volume.

In an example, the marking can be processed in such a way that the marking has a target shape post-processing, with the volume of the target shape being smaller than the volume of the marking before the marking was processed. For example, the marking can have an original shape prior to the processing. This original shape can be converted into a target shape by the processing of the marking in accordance with the first aspect. For example, the target shape can be a predefined intended shape. The predefined intended shape can be, e.g. a certain geometry which is defined by way of accurate dimensions. For example, the target shape can be a conical shape (with defined dimensions, for instance specific radii on the top side and lower side of the cone). Likewise, the target shape can be a cylindrical shape and/or an at least partially embodied elliptical shape which is defined by way of appropriate dimensions. The processing can be implemented in such a way that the target shape falls within a specific range of predetermined dimensions of the chosen geometry of the target shape. Thus, manufacturing variations can usually not be precluded, and so this approach ensures that the target shape is at least within a predefined specification. For example, the target shape need not necessarily have a specific predefined shape. Rather, an essential characteristic of the target shape can be that the latter has a smaller volume than the original shape. Thus, a simple investigation can confirm whether the target shape was reached, by use of verification as to whether the volume of the target shape is smaller than the volume of the original shape.

In an example, the volume of the marking can be reduced by at least 10%, (preferably) at least 30%, (more preferably) at least 50% and (most preferably) at least 90%. It is also conceivable for the volume of the marking to also be able to be reduced by at least 95%.

In an example, at least 5%, (preferably) at least 10%, (more preferably) at least 20% and (most preferably) at least 30% of the volume of the marking may remain. In an example, at least 40%, (preferably) at least 50%, (more preferably) at least 70% and (most preferably) at least 90% of the volume of the marking may further remain.

For example, the second volume of the marking may comprise (essentially) 10% of the first volume. For example, the second volume may comprise (essentially) 20% of the first volume. For example, the second volume may also comprise (essentially) 30%, 40% and/or 50% of the first volume.

Thus, according to the invention, a significant material residue of the marking may remain, the latter not corresponding to a trace remain of the marking material. For example, this material residue can be detected by way of a scanning electron microscope.

In an example, the marking can be deposited on an imaging structure of the object. For example, the imaging structure can be a radiation-absorbing and/or phase-shifting lithography structure. For example, the imaging structure may comprise a pattern element of a mask. For example, the imaging structure may comprise a line-shaped structure of a certain width. For example, the imaging structure may comprise one or more layers. The marking may be applied to, e.g. an (upper) plateau of the imaging structure (e.g. to a top-most layer of the imaging structure). For example, the imaging structure may be present in the form of a mesa, with the marking being deposited on the mesa.

In an example, the marking may be applied directly to the imaging structure without the need for a layer (e.g. a sacrificial layer) to be applied between the marking and the imaging structure. As a result of the advantages within the scope of reducing the volume of the marking as mentioned herein, it is possible e.g. to manage without an easily removable sacrificial layer present between the imaging structure and marking. This represents an advantage since the deposition of a sacrificial layer on the imaging structure represents a further procedural step which can be avoided using the approach described herein. Further, it is also possible to manage without a subsequent removal of the sacrificial layer (e.g. together with the marking) since the reduction in the marking volume can be chosen such that the optical properties of the lithography object are not impaired.

According to the invention, the particle beam and the etching gas can be directed to the marking on the imaging structure in order to reduce the volume of the marking, with the marking remaining on the imaging structure. In an example, the etching gas can be introduced for example locally in the surroundings of the marking (e.g. via a gas nozzle). In an example, a pixel raster can be placed over the marking, wherein one or more pixels are able to cover the marking. When processing the marking, the particle beam can be directed at the one or more pixels in order to carry out the method described herein.

In an example, the imaging structure may adjoin a capping layer of the object. The capping layer may comprise, e.g. ruthenium, with other materials also being conceivable. For example, the capping layer may comprise quartz. Regions of the object where the capping layer is exposed may be interpreted as, e.g. clear regions since an exposure radiation is not absorbed at these sites. Thus, the marking may be applied to, e.g. a clear region of the object if the marking is applied to the capping layer.

In an example, the marking may be applied directly to the capping layer of the mask without the need for a layer (e.g. a sacrificial layer) to be applied between the marking and the capping layer. As a result of the advantages within the scope of reducing the volume of the marking as mentioned herein, it is possible e.g. to manage without an easily removable sacrificial layer present between the capping layer and marking. This represents an advantage since the deposition of a sacrificial layer on the imaging structure represents a further procedural step which can be avoided using the approach described herein. Further, it is also possible to manage without a subsequent removal of the sacrificial layer (e.g. together with the marking) since the reduction in the marking volume can be chosen such that the optical properties of the lithography object are not impaired.

Regions of the object where material of the imaging structure is present might be interpreted as, e.g. opaque regions since an exposure radiation is absorbed at these sites. For example, the marking may also be applied to an opaque region (e.g. to an imaging structure as described herein). Thus, imaging structures may be applied to the capping layer of the object.

In an example, the volume can be reduced such that a height of the processed marking in relation to the imaging structure is smaller than a height of the imaging structure in relation to the object. The height of the (processed) marking in relation to the imaging structure can be defined as, e.g. a height of the (processed) marking in relation to the (upper) plateau of the imaging structure. The height of the imaging structure in relation to the object can be, e.g. the height of the imaging structure in relation to the capping layer to which the imaging structure may be adjacent.

Thus, the marking may be reduced in height according to the invention. In an example, the height of the marking can be reduced from a first height to a second height (e.g. to a second predetermined target height). For example, the first height might correspond to the height of the marking which the latter had before the method of the first aspect was carried out. For example, the first height might correspond to the original height of the marking, which the latter had following the deposition on the object. For example, the first height might also deviate from the original height (e.g. caused by deposition and/or etching processes when raster-scanning the marking, as described herein).

The second height might correspond to the height of the marking which the latter has following the method of the first aspect.

In an example, the marking can be processed in such a way that the height of the processed marking (in relation to the imaging structure) is at least 10%, (preferably) at least 30%, (more preferably) at least 50% and (most preferably) at least 90% less than the height of the imaging structure (in relation to the object). In an example, the marking can be processed in such a way that the height of the processed marking is at least 95% less than the height of the imaging structure.

In an example, the marking can be processed in such a way that the height of the processed marking (in relation to the imaging structure) corresponds to at least 5%, preferably at least 7%, more preferably at least 10% and most preferably at least 12% of the height of the imaging structure (in relation to the object).

In an example, the volume is reduced in such a way that the second height of the marking corresponds to at least 5%, (preferably at least) 10%, (more preferably) at least 20% and (most preferably) at least 40% of the first height of the marking. In an example, the volume is reduced in such a way that the second height corresponds to at least 50%, (preferably at least) 60%, (more preferably) at least 70% and (most preferably) at least 90% of the first height.

For example, the reduction in height might be advantageous if the lithography object is used for an inclined exposure. In this case, the object can be exposed by, e.g. incident radiation that is inclined vis-à-vis the object plane. Thus, an incidence of the radiation during the exposure might be at an angle to the capping layer of the object. Further, the radiation can be reflected by the object at a corresponding angle. For example, the inclined exposure might be found in EUV lithography.

Against this background, a critical height of the marking might cause shadowing during the inclined exposure incidence. For example, the shadowing may project beyond the imaging structure, for example onto the capping layer. This might induce an optical error. Likewise, a critical height of the marking might shadow a radiation reflected obliquely by the object (as a result of the inclined exposure). This mechanism might also induce an optical error (e.g. a deviation from a predetermined specification in lithography). According to the invention, a height reduction can also be implemented in relation to, e.g. no (substantial) optical errors being created during lithography, even in the case of an inclined exposure.

In an example, the imaging structure might comprise a lateral dimension (e.g. a width) of no more than 100 nm, (preferably) no more than 80 nm, (more preferably) no more than 60 nm and (most preferably) no more than 40 nm. In an example, the imaging structure may also comprise a lateral dimension (e.g. a width) of no more than 30 nm or no more than 20 nm. For example, the width of the imaging structure may encompass a width of between 10 nm and 100 nm. As described herein, the width of the imaging structure may comprise, e.g. a lateral dimension of the imaging structure (e.g. a line width, as known in the industrial sector). For example, the width may comprise a line width of a pattern element (e.g. an absorber structure). As mentioned, lithography objects may comprise imaging structures with structure dimensions below 100 nm. For example, this may be the case for EUV lithography objects.

In the case of such delicate structures with dimensions below 100 nm, a complete removal of a marking (e.g. present on the structure) might not always be advantageous (as described herein). For example, EUV lithography masks may comprise imaging structures with a width of the order of 60 nm (e.g. less than or equal to 60 nm). By way of reducing the volume of the marking, the method according to the first aspect can ensure that the interfering effect of the marking on the lithography can be reliably rectified, even for such objects. The risk of damaging the structures with dimensions below 100 nm can be minimized in the process.

In an example, a lateral dimension (e.g. a width) of the marking prior to processing might correspond to at least 50% of a lateral dimension (e.g. a width) of the imaging structure. Thus, a dimension of the marking would be of the order of a structure dimension in this case. In such an example, shadowing by the marking may occur during lithography, e.g. even in the case of perpendicular illumination or transillumination of the object, and this shadowing may cause an optical error in a lateral effective region around the marking. Such optical appearances can also be minimized or rectified using the method described herein. It is also mentioned that the lateral optical error may also occur in the case of an inclined exposure of the object (e.g. by preference in one direction). For example, the lateral dimension of the marking may comprise a lateral dimension of the marking which the latter has at an interface to a surface on which the marking is deposited. For example, the lateral dimension of the marking may comprise a diameter of the marking. For example, the marking may have a circular or elliptical shape at the interface to the surface on which the marking is deposited. In this case, the lateral dimension of the marking may comprise, e.g. a diameter of this circle or a diameter of the elliptical shape.

In an example, a lateral dimension of the marking may comprise at least 60%, (preferably) at least 70%, (more preferably) at least 80% and (most preferably) at least 90% of a width (or lateral dimension) of the imaging structure.

In an example, the imaging structure may comprise a width of no more than 70 nm, with the marking comprising a width of at least 25 nm. In an example, the imaging structure may comprise a width of no more than 60 nm, with the marking comprising a width of at least 30 nm.

In an example, the volume of the marking can be reduced in such a way that a width of the marking is reduced. In an example, a width of the marking can be reduced from a first width to a second width. The first width of the marking may correspond to the marking which the latter has prior to the method of the first aspect being carried out. For example, the first width may correspond to the original width of the marking, which the latter had following the deposition. For example, the first width might also deviate from the original width (e.g. due to deposition and/or etching procedures when raster-scanning the marking, as described herein). The second width may correspond to the width which the marking had following the method of the first aspect. The second width can be smaller than the first width.

In an example, a marking can be deposited with an offset on an imaging structure. Thus, one side of the marking may be, e.g. closer to one edge of the imaging structure than another side of the marking. For example, it might be useful to process the width of the marking. For example, the marking might be processed on the side which is closer to an edge of the imaging structure. Thus, e.g. lateral effects on the corresponding side can be minimized (as described herein). However, it is also conceivable that the width of the marking is reduced homogeneously (i.e. uniformly). For example, in the case of a circular diameter of a marking, this may represent a reduction in the radius of the circular diameter.

In an example, the method also comprises a processing site on the object being processed by the particle beam. Processing may comprise, e.g. a repair of the object (e.g. the repair of missing and/or excess material on the mask and/or an optical correction of the mask). In this case, at least one correction of the particle beam can be undertaken, based at least in part on a position of the marking. Processing the processing site may also comprise the provision of a gas (e.g. a provision of an etching gas and/or deposition gas).

In an example, the method may further comprise a processing of a foreign material of the object in surroundings of the marking by the particle beam and the etching gas in order to reduce the volume of the foreign material. The concept of the invention accordingly also includes the removal of interfering material from around the marking. In an example, the foreign material may depend on the presence of the marking. For example, foreign material might be created around the marking (and/or on the marking) during the deposition of the marking and/or a raster-scanning of the marking (e.g. as reference structure).

As a result of its geometric dimensions, this foreign material might also cause an optical error of the object during lithography (as described analogously herein for a marking). The features and aspects of the method described herein for the processing of the marking may thus also apply accordingly to the processing of the foreign material.

Thus, the volume of the foreign material might be reduced in an example, with the foreign material remaining on the object.

The features described herein regarding the relative reduction in the volume of the marking may also accordingly hold true for or be applied to the reduction of the volume of the foreign material. For example, within the scope of reducing the volume of the foreign material, the percentage reductions in the volume of the marking as described herein may also correspond to the percentage reduction in the foreign material.

The foreign material can be removed from the object in another example. For example, the foreign material can be removed (substantially) without residue. For example, the foreign material may have different properties to the material of the marking. For instance, it may be the case that the foreign material was deposited parasitically (e.g. on the basis of a deposition condition not actually wanted but present). Thus, to remove the optical error induced by the foreign material, it may be (e.g. necessarily) required to remove the foreign material (substantially without residue). In such a case, it may be worthwhile to, e.g. take the risk of over-etching the foreign material despite potential disadvantages as the advantages of an optically error-free mask may outweigh these disadvantages.

In an example, the surroundings of the marking in which the foreign material is present can be located within a radius of no more than 1 μm (and/or within a radius of no more than 10 μm and/or within a radius of no more than 100 nm) from the marking. However, the surroundings of the marking in which the foreign material is present may also depend on the deposition of the marking and/or the processing when raster-scanning the marking, and so the surroundings need not (necessarily) be limited to absolute values.

In an example, the foreign material may comprise a deposition material which was created when the marking was deposited. For example, the deposition of the marking may comprise a particle beam-induced deposition. This can comprise, e.g. an electron beam-induced and/or ion beam-induced deposition. A situation that may arise in such deposition methods is that particles additionally accumulate or collect at local sites (e.g. by reflection, diffraction and/or secondary emission of particles, etc.) as a result of the effect of the particle beam on the object. These local sites might be offset from the actual point of incidence of the particle beam. A deposition might likewise arise at these local sites on account of the presence of particles there. However, this might be unwanted from a technical point of view. Thus, the usual idea from a technical point of view is that deposition material should only be created at the point of incidence of the particle beam so as to be able to create a deposition geometry in a defined manner by way of the alignment of the particle beam. Thus, the effect described herein may have led to a parasitic foreign material having been deposited (e.g. at a site to which the particle beam was not directed during the deposition) locally offset from and in addition to the desired deposition geometry (e.g. at sites to which the particle beam was directed during the deposition).

According to the invention, this foreign material locally offset from the marking can be processed using one of the methods described herein.

In an example, the foreign material may comprise a foreign material around the marking (and/or on the marking). For example, the foreign material can be radially spaced apart from the marking. For example, the foreign material can be present in the form of a halo around the marking. Foreign material around the marking might not always have, e.g. a defined shape or defined thickness. For example, the foreign material might appear like a halo around the marking in a recording (e.g. a scanning electron microscope image). As described herein, the foreign material in the form of a halo may have been created parasitically, e.g. during an electron beam-induced deposition of the marking, for example due to an electron accumulation around the marking during the deposition. For example, the foreign material in the form of a halo may comprise a material whose thickness drops off exponentially (e.g. in the radial direction starting from the marking). For example, this thickness profile may appear as a halo (e.g. around the marking) in a scanning electron microscope image.

It is also conceivable that the foreign material is arranged, e.g. shaped like a ring and/or in the form of an ellipse around the marking.

In an example, the foreign material may comprise a deposition material which was created when the marking was raster-scanned within a scanning field, preferably during a repair of the object. For example, the marking can be raster-scanned as a reference structure for a drift correction of the particle beam within the scope of processing the object (e.g. a particle beam-induced repair of a defect).

In an example, the foreign material can be applied directly to the object without the need for a layer (e.g. a sacrificial layer) to be applied between the marking and the object. For example, the foreign material can be applied directly to the imaging structure and/or the capping layer. As a result of the advantages within the scope of reducing the volume of the marking as mentioned herein, it is possible e.g. to manage without an easily removable sacrificial layer present between object and marking. This represents an advantage since the deposition of a sacrificial layer on the lithography object represents a further procedural step which can be avoided with the approach described herein. Further, it is also possible to manage without a subsequent removal of the sacrificial layer (e.g. together with the marking and the foreign material) since the reduction in volume of the marking can be chosen such that the optical properties of the lithography object are not impaired.

Thus, it should be mentioned that the approaches for reducing the volume of the marking and/or of the foreign material as mentioned herein may in certain cases render obsolete the additional integration of a sacrificial layer during the processing of the object (e.g. within the scope of a mask repair).

As described herein, charging effects may arise during a repair and/or processing of the object with the particle beam, resulting in the particle beam inadvertently being deflected (and not being incident on an intended position). Thus, the position of a marking is usually used as a reference structure serving the adaptation or correction of the particle beam on the basis of the position of the marking. The correction can ensure that the particle beam is able to be incident on a desired position (e.g. on a desired processing and/or repair site on the object). For example, a position of the marking must be determined multiple times here for the purpose of correcting the particle beam within the scope of a repair and/or processing.

To effectively use the marking as a reference structure in the process, it is possible to arrange a local scanning field around the marking, with the scanning field being raster-scanned in full by the particle beam for the purpose of determining the position of the marking. The reason for this lies in the fact that when the position of the marking is determined, the position thereof may likewise drift (or vary) on account of the charging effects. By virtue of a scanning field with a defined size being (initially) placed around the marking, it is possible to address a position drift of the marking within the scanning field by the particle beam. For example, if the entire local scanning field is raster-scanned, the assumption can be made that the particle beam should ultimately be incident on the marking for imaging purposes, even if the position of the marking drifts (within the scanning field). Within the scope of processing the object, the particle beam can thus be driven into a desired processing site, for example for a particle beam-induced etching and/or deposition at the processing site. For a drift correction, the particle beam can then also raster-scan the scanning field around the marking in addition to the actual processing site, in order to be incident on or determine the position of the marking.

What may occur in this context is that the processing of the object comprises a particle beam-induced deposition with a deposition gas at a processing site. For example, this may be a mask repair, wherein the processing site may comprise a defect of the mask (e.g. a defect where material of the mask is missing, e.g. a clear defect of the mask). A deposition gas can be provided at the processing site of the object for the particle beam-induced deposition there. For example, the deposition gas can be introduced locally over the processing site, with it also being conceivable that a deposition gas is introduced globally over the object. By virtue of the particle beam being directed to the processing site, an appropriate deposition reaction can be induced via the deposition gas present there.

What may arise during such processing is the case where providing a deposition gas at the processing site of the object leads to this deposition gas also being present in the region of the marking. Consequently, e.g. the scanning field around the marking may also comprise the deposition gas. If the scanning field comprising the marking is raster-scanned during such processing of the object for the purpose of correcting the particle beam, then a particle beam-induced deposition of foreign material may accordingly occur in the scanning field.

In this case, this foreign material may be present around the marking (or even on the marking). For example, this foreign material may (substantially) correspond to the lateral dimensions of the scanning field. For example, this may be identifiable in a scanning electron microscope image; for example, it is possible in the process to detect rectangular foreign material, within which a drift correction marking is situated.

According to the invention, such foreign material can also be reduced in terms of volume and/or removed completely from the object.

In an example, the foreign material can be present next to an imaging structure of the object and/or on an imaging structure of the object. The concept of the invention thus also includes the removal of interfering foreign material from clear regions and/or opaque regions on the object. The foreign material next to and/or on the imaging structure of the object may result, e.g. from the scanning field around the marking.

In an example, the marking may be applied to the imaging structure. In the case of imaging structures with comparatively large structure dimensions (e.g. with widths greater than 130 nm), e.g. the scanning field (as described herein) may be designed such that the latter only comprises a region in which imaging structure material is present. Thus, if a deposition occurs there during the raster-scanning of the scanning field, then the corresponding deposition material can only be present on the imaging structure. Since the deposition material is only present on the (e.g. radiation-absorbing) imaging structure in this approach, one previous assumption made in this context was that it is consequently not possible to induce any (significant) optical error.

However, an optimal determination of the marking position (usually) requires a certain minimum size of the scanning field. Thus, what may occur as the dimensions of the imaging structures become increasingly smaller (e.g. below 100 nm) is that the scanning field comprises not only a region which covers the material of the imaging structure but (necessarily) also a second region which covers a region next to the imaging structure. Accordingly, the second region of the scanning field may comprise a clear region of the object containing no material of the imaging structure. When the scanning field is raster-scanned, foreign material may in the process also be deposited in the second region and consequently be deposited directly on a clear region of the object (e.g. if deposition gas is present in the scanning field, as described herein). Thus, according to the methods described herein, this parasitically created foreign material next to the imaging structure can be reduced in terms of volume and/or removed, for example in order to avoid optical errors during lithography.

Further, as the dimensions of the imaging structures become increasingly smaller and/or the demands on lithography objects become increasingly complex, it is also no longer possible to neglect the foreign material on the imaging structure (e.g. created when raster-scanning the scanning field). For example, this foreign material may also cause a deviation from a lithography specification in the case of an inclined exposure during the lithography. Thus, according to the methods described herein, parasitically created foreign material on the imaging structure can be reduced in terms of volume and/or removed, for example in order to avoid optical errors during lithography.

In an example, the method may further comprise: selecting the etching gas, the etching gas being selected at least in part on the basis of a provided deposition gas used to deposit the marking and/or a foreign material on the object in surroundings of the marking. Thus, the etching gas for processing the marking and/or for processing the foreign material may be based on, e.g. a deposition material of the marking and/or of the foreign material. Thus, in an example the method may comprise: selecting the etching gas, the etching gas being selected at least in part on the basis of a material comprised by the marking and/or the foreign material.

As described herein, the parasitically deposited foreign material may be the result of deposition gas which is present in the scanning field and used to process the object at a processing site (e.g. within the scope of a repair of a defect of the object). The composition of the foreign material can thus, e.g. have a different composition to that of the marking material. The features and/or aspects, as described herein, for the assignment of etching gas to deposition gas may however also be applied accordingly to this case.

In an example, the marking is processed with a first etching gas and the foreign material is processed with a second etching gas, the second etching gas differing from the first etching gas.

In an example, the method may comprise creating the marking on the object using a particle beam and a deposition gas provided, preferably for the purpose of repairing the object (e.g. a mask repair). Which deposition gas is provided for creating the marking can, e.g. be stored in a storage unit and/or a database. Likewise, which deposition gas was used for processing at the processing site can be stored (analogously) in a storage unit and/or a database, for example.

Selecting the etching gas may comprise retrieving the deposition gas provided from the storage unit and/or database. It is subsequently possible to determine the components and/or the one or more chemical compounds of the deposition gas provided. A corresponding etching gas can be selected on the basis of the components and/or the one or more chemical compounds. For example, this can be implemented by way of a lookup table and/or a database. For example, one column of the lookup table can comprise the components and/or the one or more chemical compounds of the deposition gas. A further column might comprise the associated etching gases which are possible. An appropriate etching gas for processing the marking can be chosen by way of the lookup table on the basis of the determination of the components and/or the one or more chemical compounds. Further, any desired database in which an association between deposition gas (or deposition gas composition) and possible etching gases is stored is also conceivable.

For example, the method may also (accordingly) comprise an automatic placement or storage of an etching gas in a database and/or lookup table, for example after the marking was deposited using a specific deposition gas.

This may enable an automated method for processing the marking with a suitable etching gas.

The etching gas may comprise a halogen in an example. For example, the etching gas may comprise at least one halogen atom.

In an example, the halogen (of the etching gas) may comprise chlorine if the deposition gas comprises chromium. For example, an association between a chromium-containing deposition gas and a chlorine-containing etching gas may be stored in the database and/or in the lookup table.

For example, the chromium-comprising deposition gas may comprise chromium hexacarbonyl, Cr(CO)₆.

In an example, the halogen (of the etching gas) may (analogously) comprise chlorine if the deposition material of the marking and/or of the foreign material comprises chromium.

In an example, the etching gas may also comprise nitrogen and oxygen (if the deposition gas comprises chromium). In an example, the etching gas may (analogously) also comprise nitrogen and oxygen if the deposition material of the marking and/or of the foreign material comprises chromium.

In an example, the etching gas may comprise chlorine, nitrogen and oxygen in a compound, preferably nitrosyl chloride, NOCI, (if the deposition gas comprises chromium). For example, an association between a chromium-containing deposition gas and nitrosyl chloride as an etching gas may be stored in the database and/or the lookup table.

In an example, the etching gas may (analogously) comprise nitrosyl chloride if the deposition material of the marking and/or of the foreign material comprises chromium. In an example, the halogen may comprise fluorine if the deposition gas comprises chromium and/or if the deposition gas comprises silicon and oxygen and/or if the deposition gas comprises molybdenum. For example, an association between a deposition gas with silicon and oxygen and/or a deposition gas with molybdenum on the one hand and a fluorine-containing etching gas on the other hand may be stored in the database and/or the lookup table.

For example, the deposition gas with silicon and oxygen may comprise tetraethyl orthosilicate, TEOS.

For example, the deposition gas with molybdenum may comprise molybdenum hexacarbonyl, Mo(CO)₆.

In an example, the halogen (of the etching gas) may (analogously) comprise fluorine if the deposition material of the marking and/or of the foreign material comprises chromium.

In an example, the halogen (of the etching gas) may (analogously) comprise fluorine if the deposition material of the marking and/or of the foreign material comprises silicon and oxygen. In an example, the halogen (of the etching gas) may (analogously) comprise fluorine if the deposition material of the marking and/or of the foreign material comprises molybdenum.

In an example, the etching gas may further comprise xenon (if the deposition gas comprises chromium and/or if the deposition gas comprises silicon and oxygen and/or if the deposition gas comprises molybdenum). In an example, the etching gas may further (analogously) comprise xenon if the deposition material of the marking and/or of the foreign material comprises chromium. In an example, the etching gas may further (analogously) comprise xenon if the deposition material of the marking and/or of the foreign material comprises silicon and oxygen. In an example, the etching gas may further (analogously) comprise xenon if the deposition material of the marking and/or of the foreign material comprises molybdenum.

In an example, the etching gas may comprise fluorine and xenon in a compound, preferably xenon difluoride, XeF₂, (if the deposition gas comprises chromium and/or if the deposition gas comprises silicon and oxygen and/or if the deposition gas comprises molybdenum). For example, the fact that a deposition gas with silicon and oxygen (e.g. tetraethyl orthosilicate) is associated with xenon difluoride as etching gas may be stored in the database and/or the lookup table.

For example, the fact that a deposition gas with chromium (e.g. chromium hexacarbonyl) is associated with xenon difluoride as etching gas may be stored in the database and/or the lookup table.

For example, the fact that a deposition gas with molybdenum (e.g. molybdenum hexacarbonyl) is associated with xenon difluoride as etching gas may be stored in the database and/or the lookup table.

In an example, the etching gas may (analogously) comprise xenon difluoride if the deposition material of the marking and/or of the foreign material comprises chromium.

In an example, the etching gas may (analogously) comprise xenon difluoride if the deposition material of the marking and/or of the foreign material comprises silicon and oxygen.

In an example, the etching gas may (analogously) comprise xenon difluoride if the deposition material of the marking and/or of the foreign material comprises molybdenum.

In an example, the etching gas may comprise oxygen if the deposition gas comprises molybdenum. In this example, the etching gas need not necessarily comprise a halogen, for example. In an example, the etching gas may (analogously) comprise oxygen if the deposition material of the marking and/or of the foreign material comprises molybdenum. Within the scope of the method, a molybdenum-containing marking and/or a molybdenum-containing foreign material may also be etched using an oxygen-containing gas, in which a halogen need not necessarily be present.

In an example, the (oxygen-containing) etching gas may comprise water (if the deposition gas comprises molybdenum). For example, the etching gas may (analogously) comprise water if the deposition material of the marking and/or of the foreign material comprises molybdenum. Within the scope of the method, a molybdenum-containing marking and/or a molybdenum-containing foreign material may also be etched using water as etching gas, in which a halogen need not necessarily be present.

In an example, the marking and/or the foreign material may be further processed using an additive gas which includes oxygen. For example, the additive gas may be added to the etching gas as an oxidative component.

In an example, the additive gas may comprise water and/or nitrogen dioxide.

In an example, the etching gas may comprise nitrosyl chloride, wherein the additive gas may comprise water, if the deposition material of the marking and/or of the foreign material comprises chromium.

In an example, the etching gas may comprise xenon difluoride, wherein the additive gas may comprise water and nitrogen dioxide, if the deposition material of the marking and/or of the foreign material comprises chromium.

In an example, the etching gas may comprise xenon difluoride, wherein the additive gas may comprise water, if the deposition material of the marking and/or of the foreign material comprises tetraethyl orthosilicate.

In an example, the etching gas may comprise xenon difluoride, wherein the additive gas may comprise water, if the deposition material of the marking and/or of the foreign material comprises a silicon oxide.

In an example, the etching gas may comprise xenon difluoride, wherein it is possible to manage without an additive gas, if the deposition material of the marking and/or of the foreign material comprises tetraethyl orthosilicate and/or a silicon oxide.

In an example, the etching gas may comprise xenon difluoride, wherein the additive gas may comprise water, if the deposition material of the marking and/or of the foreign material comprises molybdenum.

In an example, the etching gas may comprise water, wherein it is possible to manage without an additive gas, if the deposition material of the marking and/or of the foreign material comprises molybdenum.

A second aspect relates to a processing of a foreign material of the object (as described herein) in surroundings of the marking by the particle beam and the etching gas for the purpose of reducing the volume of the foreign material. The features and aspects for processing the foreign material as described herein (e.g. in relation to the method of the first aspect) may also accordingly hold true for or be applied to the method according to the second aspect. In the method according to the second aspect, the foreign material (as described herein) may be processed separately in this case, without e.g. the marking being subject to noteworthy processing. Further features and/or aspects of the first method may likewise apply accordingly to the method of the second aspect. For example, the method of the second aspect may also comprise processing of a processing site of the object by the particle beam. For example, the processing may comprise repairing the object (e.g. repairing a lack and/or excess of material on the mask, and/or an optical correction of the mask). Further, the method of the second aspect may also comprise creating the marking on the object using a particle beam and a deposition gas provided, preferably for the purpose of repairing the object (e.g. a mask repair).

A third aspect relates to a method according to the second aspect, with the foreign material (only) comprising a foreign material in the form of a halo around the marking (as described herein). According to the method of the third aspect, it is thus possible to reduce the volume of a halo around the marking or remove said halo (substantially without residue), with there not necessarily being the need for processing of further foreign material. For example, it may be useful within the scope of a mask repair to only reduce the volume of the halo and/or remove the latter in a separate step. For example, the deposition material of the halo may have a different geometry and/or composition to that of the marking, with the result that processing of the halo and the marking in one related procedural step is not always advantageous.

A fourth aspect relates to a method according to the second aspect, wherein the foreign material (only) comprises a deposition material which was created when raster-scanning the marking within a scanning field, preferably during a repair of the object (as described herein). According to the method of the fourth aspect, it is thus possible to reduce the volume of a deposition material created in the scanning field or remove said deposition material (substantially without residue), with there not necessarily being the need for processing of further foreign material. For example, it may be useful within the scope of a mask repair to only reduce the volume of the foreign material in the scanning field and/or remove the latter in a separate step. For example, the deposition material of the scanning field may have a different geometry and/or composition to that of the marking (and/or of the halo). Processing of the deposition material of the scanning field and the marking in one related procedural step thus may not always be advantageous.

A fifth aspect relates to a method according to the second aspect, wherein the foreign material (only) comprises a foreign material in the form of a halo around the marking (as described herein) and wherein the foreign material comprises a deposition material created when raster-scanning the marking within a scanning field, preferably during a repair of the object (as described herein). For example, it may be useful within the scope of a mask repair to only reduce the volume of the halo and foreign material in the scanning field and/or remove this in a separate step. Processing of the deposition material of the scanning field, the halo and the marking in one related procedural step may not always be advantageous on account of the different geometries and/or compositions of these materials.

A sixth aspect relates to a method for processing a lithography object comprising processing a foreign material of the object in surroundings of a deposition material by a particle beam and an etching gas for the purpose of reducing the volume of the foreign material. For example, the deposition material may comprise any desired (e.g. locally delimited) deposition material. For example, this deposition material may have been deposited in particle beam-induced fashion. Accordingly, a concept of the invention can thus also include the removal of interfering foreign material from around any desired deposition material in particle beam-induced fashion. Thus, the invention need not necessarily be restricted to the removal of foreign material from surroundings of a deposited marking. The features of the other aspects of the invention described herein may also accordingly hold true for or be applied to the method of the sixth aspect. For example, the foreign material can be removed (substantially) completely from the object (e.g. removed substantially without residue) according to the method of the sixth aspect. For example, the volume of the foreign material can be reduced according to the method of the sixth aspect, with the foreign material remaining on the object.

For example, the foreign material processed using a method of the sixth aspect (as described analogously for the other aspects) may depend on the presence of the (e.g. locally delimited) deposition material. For example, foreign material may be created around the deposition material (and/or on the deposition material) within the scope of a particle beam-induced deposition of the (e.g. locally delimited) deposition material.

For example, the foreign material may comprise a halo which is present around the (e.g. locally delimited) deposition material (as described analogously herein for the halo of the reference marking).

For example, the (e.g. locally delimited) deposition material of the sixth aspect may comprise a repair material used to repair the lithography object. For example, a halo may have formed in the surroundings of the repair material during the particle beam-induced deposition of the repair material (as described analogously herein for the halo around the marking). This halo of the repair material may represent the foreign material whose volume is reduced using a method of the sixth aspect.

By way of example, the repair material of the sixth aspect may have been deposited for the purpose of repairing an opaque defect of the lithography object. For example, the repair material of the sixth aspect may also have been deposited for the purpose of repairing any other desired defect of the mask object.

In an example, the particle beam mentioned herein may comprise an electron beam and/or an ion beam.

A seventh aspect relates to a computer program having instructions for performing a method according to any of aspects described herein, when said instructions are carried out. For example, the computer program may comprise instructions which, when executed by a computer, are able to prompt a method according to any of the aspects described herein by a computer and/or a device.

The features of the methods described herein may be comprised accordingly in the computer program. The features (and examples) of the methods (of the first to fifth aspect) mentioned herein may thus also accordingly hold true for or be applied to the aforementioned computer program.

A further aspect relates to a memory comprising the computer program of the sixth aspect.

An eighth aspect relates to a device for processing a lithography object, comprising: means for processing a marking which had been deposited on the object, a particle beam and an etching gas being used for the processing that serves to reduce the volume of the marking such that the marking remains on the object; a computer unit which causes the device to perform a method according to any of the aspects described herein, based at least in part on an execution of a computer program of the fifth aspect.

In an example, the device comprises a memory which comprises the computer program according to any of the aspects described herein. In this example, the computer unit may be able to execute the computer program. For example, the computer program may be installed on the computer unit and hence on the device (physically/concretely).

For example, the computer unit may comprise a computer, a computing unit, a microprocessor, etc. For example, the computer unit may be communicatively coupled to the components of the device such that a signal output by the computer unit can cause a change in a component of the device.

When the computer program is executed, the latter can e.g. output an instruction which causes the device to reduce a marking volume (as described herein). In the same way, the computer program, when executed, may select e.g. an etching gas on the basis of a deposition gas (as described herein).

For example, the device may be configured to receive a value from the user, on the basis of which the volume of the marking is reduced automatically to or by a predetermined value.

In an example, it is also possible that the computer program is stored elsewhere (e.g. in a cloud) and the device merely has means for receiving instructions that arise from executing the program elsewhere. Thus, the computer program can be executed externally (e.g. on an external computer unit, on a server unit, etc.) in this case, wherein the instructions of the computer program are transmitted to the receiving means of the device. The means for receiving the instructions may be communicatively coupled to the computer unit of the device, for example. For example, the receiving means may comprise a receiver unit configured to receive and/or process instructions via a wireless and/or wired connection.

For example, the synergy of computer program and corresponding device may allow the method to run in automated or autonomous fashion within the device. Consequently, it is also possible to minimize the intervention, for example by an operator, and so it is possible to minimize both the costs and the complexity when processing (lithography) objects.

It should be mentioned that, as a matter of principle, the features (and examples) of the methods mentioned herein may also accordingly hold true for or be applied to the mentioned device. The features (and also examples) of the device that are specified herein may also accordingly hold true for or be applied to the methods described herein.

A ninth aspect relates to a lithography object which was processed using a method according to any of the methods described herein.

A tenth aspect relates to a method of processing a semiconductor-based wafer, comprising: a lithographic transfer of a pattern associated with a lithography object to the wafer, wherein the object was processed using a method of the aspects described herein. The lithographic transfer may comprise a lithography method for which the object is designed (e.g. EUV lithography, DUV lithography, i-line lithography, etc.). For example, the method of this aspect may comprise a provision of a beam source of electromagnetic radiation (e.g. EUV radiation, DUV radiation, i-line radiation, etc.). This may additionally comprise a provision of a developable resist layer on the wafer. The lithographic transfer may also be based at least in part on the beam source and the provision of the developable resist layer. It is possible here, for example, by use of the radiation from the beam source, to image the pattern onto the resist layer (in a transformed form).

### BRIEF DESCRIPTION OF DRAWINGS

Technical background information and exemplary embodiments of the invention are described in the following detailed description, with reference being made to the figures:

FIG. 1 shows a scanning electron microscope image of a mask defect and reference markings in the left partial image, the reference markings being used when processing the defect for the purpose of correcting a particle beam. The right partial image illustrates a complete removal of a reference marking as per the prior art.

FIG. 2 schematically illustrates a plan view of an exemplary reference marking on an imaging structure, which can be processed using a method according to the invention.

FIG. 3 schematically illustrates a side view of the exemplary reference marking from FIG. 2, which can be processed using a method according to the invention.

FIG. 4 schematically illustrates a side view of a reference marking volume reduction according to a method according to the invention.

FIG. 5 schematically illustrates a plan view of a scanning field used to determine the position of the reference marking for the purpose of correcting the particle beam.

FIG. 6 schematically shows a plan view of a foreign material which was created when the scanning field was raster-scanned and which can be processed in accordance with a method according to the invention.

FIG. 7 schematically shows a side view of the foreign material which was created when the scanning field was raster-scanned and which can be processed in accordance with a method according to the invention.

FIG. 8 schematically shows a plan view of a foreign material which is in the form of a halo present around the marking and which can be processed in accordance with a method according to the invention.

FIG. 9 schematically shows a side view of the foreign material which is in the form of a halo present around the marking and which can be processed in accordance with a method according to the invention.

FIG. 10 schematically shows an exemplary device according to the invention.

### DETAILED DESCRIPTION

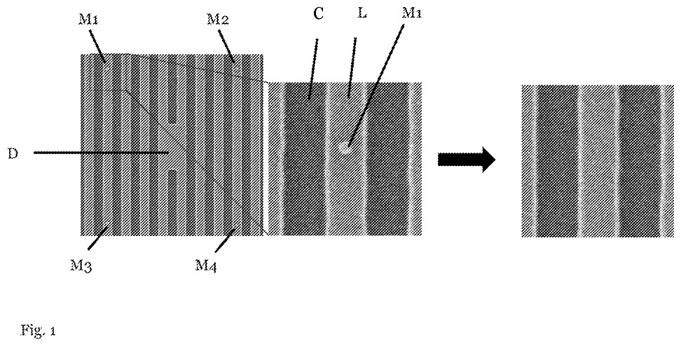

FIG. 1 shows a scanning electron microscope image of a lithography mask defect D and reference markings (M1, M2, M3, M4) in the left partial image, the reference markings being used when processing the defect D for the purpose of correcting a particle beam. In this context, FIG. 1 elucidates a procedure according to the prior art.

In FIG. 1, the defect D corresponds to excess mask material. For example, imaging structure material is present in the region of the defect D, even though this should not be the case according to the mask design. Thus, the defect D may represent an opaque defect since the defect region acts in beam-absorbing and/or phase-shifting fashion. However, according to the mask design, the defect region should represent a clear region, in which a targeted absorption of radiation is not envisaged.

For example, the defect D can be processed using a known repair method. For example, the defect D can be processed using an electron beam-induced etching process, by means of which the excess material of the defect D is etched and hence removed.

It should be mentioned that the defect D in FIG. 1 only represents an exemplary defect. There can also be mask defects where mask material is missing. For example, material may be missing from an imaging structure of the mask. For example, such defects may represent clear defects since the defect region does not have a radiation-absorbing and/or phase-shifting effect. However, according to the mask design, such a defect region should represent an opaque region in which a targeted absorption of radiation (or a phase shift) is envisaged. For example, clear defects can be repaired by way of an electron beam-induced deposition in the defect region.

Usually, a repair shape which comprises, e.g. a pixel grid can be used for defect processing. The repair shape may comprise the defect (e.g. its area), with the electron beam being directed at the pixels in the pixel grid in order to cause, e.g. an electron beam-induced deposition and/or etching there. For the defect repair, the defect may be exposed to an appropriate deposition gas and/or etching gas.

As described herein, the particle beam-induced repair may require the particle beam (e.g. the electron beam) to be corrected with the aid of reference markings. For example, this may comprise a drift correction for the particle beam, based on a determination of the reference marking position while the defect is processed.

Four reference markings M1, M2, M3, M4 are arranged around the defect D in the left partial image of FIG. 1. For example, the reference markings M1, M2, M3, M4 may have been deposited on the mask prior to the repair of the defect D.

The central partial image in FIG. 1 depicts a first reference marking M1 of the four reference markings M1, M2, M3, M4 in enlarged fashion. In this example, the first reference marking M1 has been applied to an imaging structure L. A clear region is situated next to the imaging structure L, wherein, in the clear region, a capping layer C of the mask is identifiable in the scanning electron microscope image by way of a different contrast.

As described herein, the reference markings M1, M2, M3, M4 might cause an optical error during a lithographic method for the mask. For example, a deviation in the optical image might arise when the mask is exposed in the region of the reference markings M1, M2, M3, M4. For example, the reference markings might lead to an infringement of a specification in an aerial image of the mask.

The prior art has disclosed the complete removal of the reference markings (e.g. by way of etching and/or wet-chemical cleaning).

By way of example, the right partial image in FIG. 1 illustrates the result of a complete removal of the first reference marking M1 in accordance with the prior art. It is possible to identify that there has been a (substantially) residue-free removal of the material of the first reference marking M1. This can be perceived by the fact that no material of the first reference marking M1 can be identified in the scanning electron microscope image in the right partial image of FIG. 1.

As described herein, a complete removal of the reference markings might not always be optimal as the dimensions of the mask structures (e.g. the imaging structures) become increasingly smaller and/or the demands on the mask materials become increasingly complex. For example, as a result of the reduction in size of the imaging structures on the mask, the dimensions of the reference markings are coming ever closer to the dimensions of the imaging structures. However, a certain minimum dimension of the reference markings might be necessary from a technical point of view in order to reliably determine a reference marking position for the particle beam correction. Thus, as described herein, a complete removal of the reference markings might not always be suitable for all masks and/or reference markings.

However, without processing, the reference markings might lead to optical errors during the lithography. For example, when structure widths of the mask structures are of the order of the reference markings (e.g. in the case of structure widths below 60 nm), shadowing effects might arise in the case of, e.g. a perpendicular exposure or transillumination since (optically) there is a lateral projection over the structures. For example, this may be the case for masks for UV lithography and/or for DUV lithography.

With the increasingly smaller structure widths (e.g. structure widths below 60 nm), shadowing effects can likewise arise in the case of, e.g. an inclined exposure on account of the vertical extent of the reference markings. In this case, for example, the radiation incident on the mask and/or the radiation reflected by the mask might be shadowed. In this context, it should be mentioned that the ever-smaller dimensions of the mask structures may lead to the reference marking (as a result of the required minimum dimension) possibly being, e.g. twice as high as the height of an imaging structure (e.g. of a mask absorber). Thus, the reference markings may cause comparatively pronounced shadowing effects in the case of an inclined exposure. For example, there might be an inclined exposure of the mask within the scope of EUV lithography. Thus, the invention also relates to, e.g. EUV masks for EUV lithography.

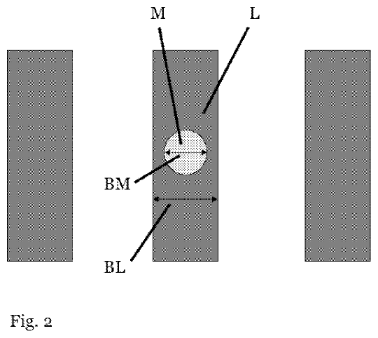

In a plan view, FIG. 2 schematically illustrates an exemplary reference marking on an imaging structure, which can be processed using a method according to the invention. It is possible to identify a reference marking M, which was deposited on an imaging structure L. Two further exemplary imaging structures of the mask are sketched out next to the imaging structure L.

The reference marking M may have a reference marking width BM. The imaging structure L may have a structure width BL. As mentioned herein, the structure widths BL of imaging structures may become increasingly smaller, while minimum widths for the reference marking width BM may still be required from a technical point of view. Such a situation is depicted in FIG. 2 by way of example. Thus, it is possible to identify that the reference marking width BM makes up more than 50% of the structure width BL.

For example, the reference marking width BM may comprise a width of at least 20 nm, at least 30 nm, at least 50 nm in such a case. For example, the reference marking width can be between 20 and 100 nm.

In such a case, the structure width BL of the imaging structure L, on which the reference marking M has been deposited, may comprise a width of, e.g. no more than 100 nm, no more than 70 nm, no more than 60 nm, no more than 40 nm and/or no more than 30 nm.

For example, the structure width BL might be of the order of 100 nm, while the reference marking width BM might be 50 nm. For example, the structure width BL might be of the order of 60 nm, while the reference marking width BM can be in the range between 30 and 40 nm.

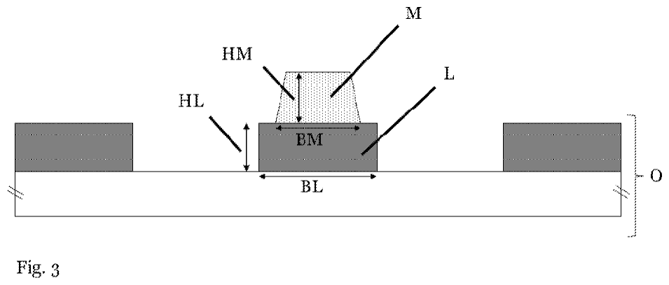

FIG. 3 schematically illustrates a side view of the exemplary reference marking from FIG. 2, which can be processed using a method according to the invention. A simplified side view through a mask O is depicted. The representation is intended to mainly illustrate the dimensions of the imaging structure L and of the reference marking M schematically.

Thus, the imaging structure L may have a structure height HL. The structure height HL may be defined in relation to a capping layer of the mask O which is adjoined by the imaging structure L (as illustrated schematically in FIG. 3). For example, the structure height HL might comprise a height of no more than 100 nm, no more than 80 nm, no more than 50 nm, no more than 30 nm. The structure width BL of the reference marking (as already explained in FIG. 2) is also plotted in FIG. 3.

In a plan view, the reference marking M might have, e.g. a substantially circular shape (as depicted in FIG. 2). In an example, the reference marking M might also have, e.g. an elliptical shape in a plan view.

Further, the reference marking M, which was deposited on the imaging structure L, is identifiable in FIG. 3. It is evident from the side view that the reference marking can have a reference marking height HM. The reference marking height HM might be defined in relation to the plateau of the imaging structure on which the reference marking is deposited (as clarified in FIG. 3). For example, the reference marking height HM might comprise a height of no more than 200 nm, no more than 100 nm, no more than 80 nm, no more than 70 nm, no more than 40 nm. The reference marking height HM might also comprise, e.g. a height of no more than 10 nm or no more than 30 nm. Thus, it should be mentioned that the reference marking height HM might have, e.g. a height of between 10 nm and 200 nm.

In a side view, the reference marking M may have a cross section with, e.g. a conical shape (as depicted in FIG. 3). However, in a side view, the reference marking M may also have a cross section with, e.g. a cylindrical shape and/or an at least partially embodied elliptical shape. A width of the reference marking at the tip thereof can be smaller than the width of the reference marking at the plateau of the imaging structure L (as evident in FIG. 3). The width of a marking (as described herein) or the reference marking width BM can mean the maximum width of the reference marking. It is also conceivable that the reference marking width BM corresponds to a width of the reference marking which can be gathered from a plan view of a scanning electron microscope image.

It should be noted that the reference marking M might also have a cylindrical and/or cuboid shape. Further, any other desired shape is also conceivable.

As described herein, a complete removal of the reference marking M might not always be optimal if the structure dimensions (e.g. the structure width BL and/or the structure height HL) of the mask are of the order of the dimensions of the reference marking M (e.g. of the order of the reference marking width BM and/or reference marking height).

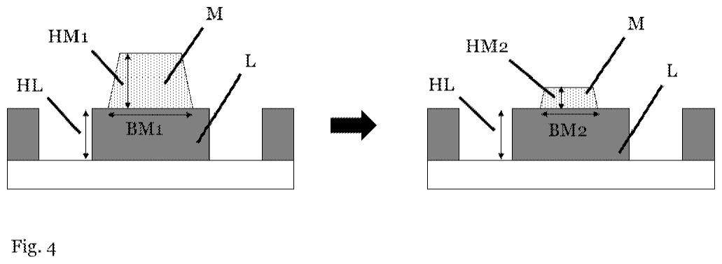

FIG. 4 schematically illustrates a side view of a reference marking M volume reduction according to a method according to the invention. A first reference marking height HMI of the reference marking can be identified in the left partial image. Further, a first reference marking width BMI of the reference marking is also identifiable in the left partial image. In general, the reference marking may comprise a first volume in the left partial image. For example, the first volume might correspond to the volume of the reference marking which the latter had after the mask defect repair (or directly after the reference marking deposition). Subsequently, the first volume can be reduced in accordance with the method described herein. The result of the volume reduction is depicted in the right partial image of FIG. 4.

It is possible to identify that, e.g. the height of the reference marking M was reduced. Following the volume reduction, the reference marking has a second reference marking height HM2, which is lower than the first reference marking height. An optical error when exposing the mask can consequently be avoided. For example, an optical error within the scope of an inclined exposure of the mask in particular can be avoided, since the reduction in height can avoid shadowing effects during an inclined exposure.

It can likewise be identified that there was, e.g. a reduction in the reference marking M width. Following the volume reduction, the reference marking has a second reference marking width BM2, which is less than the first reference marking width. An optical error when exposing the mask can consequently be avoided. For example, a lateral optical error in particular, which might arise due to a reference marking that is too wide, can be avoided.

For example, the example in FIG. 4 can manage without a sacrificial layer between the marking M and the imaging structure L. Thus, there are known approaches which integrate a sacrificial layer between the marking M and imaging structure L in order to subsequently facilitate the removal of the marking together with the sacrificial layer. However, this requires the additional procedural steps in which the sacrificial layer is initially deposited, the marking is subsequently deposited and ultimately the sacrificial layer is removed together with the marking. For example, it is possible to manage without this comparatively complex procedure integration using the approaches described herein.

For example, the volume can be reduced by way of electron beam-induced etching with an etching gas. It is conceivable that the electron beam is directed statically at the reference marking. In another example, the electron beam can be directed dynamically at the reference marking within the scope of a temporal interaction (e.g. the electron beam can be directed at two or more sites of the reference marking M when the volume is reduced).

Further, it is also conceivable that the volume reduction only comprises a reference marking height reduction. For example, the volume reduction may only comprise a reference marking width reduction. In a further example, the volume reduction for the reference marking may comprise a first step of height reduction and a second step of width reduction.

An exemplary workflow of the method according to the invention is intended to be explained once again hereinbelow. Initially, the method may comprise a detection of a defect on a mask. Subsequently, one or more reference markings can be deposited, and these can be used to repair the defect (e.g., for a correction of an electron beam). The defect can subsequently be repaired. This may comprise an electron beam-induced etching and/or an electron beam-induced deposition in the defect region. Subsequently, the volume of the reference markings can be reduced, as described herein.

As described herein, the method need not be restricted to the reduction of reference marking volumes but can also comprise the processing of foreign material in the surroundings of a reference marking.

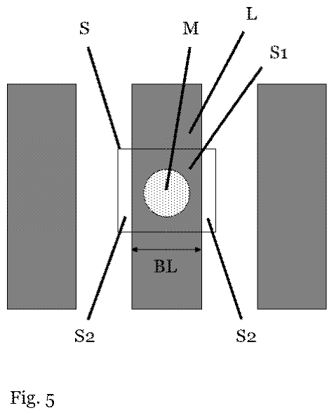

In this respect, FIG. 5 schematically illustrates a plan view of a scanning field S which can be used to determine the position of the reference marking M for the purpose of correcting the particle beam. It is possible to identify that the scanning field S is placed around a reference marking M. In this context, the entire scanning field S can be raster-scanned for the purpose of determining the position of the reference marking M. The scanning field S allows a position drift of the reference marking M within the scanning field S to be addressed, said position drift possibly being induced when the mask is processed with an electron beam. However, a minimum size of the scanning field S might be required to address the position drift of the reference marking M. For example, a scanning field that is too small might increase the risk of the electron beam not striking the reference marking M on account of the electron beam drift. Consequently, it would not be possible to determine the position of the reference marking M (and perform an accompanying drift correction).

Thus, as the dimensions of mask structures become ever smaller (e.g. ever smaller structure widths BL of the imaging structures L), the scanning field S can project beyond the width of a mask structure. This is depicted by way of example in FIG. 5. For example, the scanning field S can comprise a first scanning field region S1. In FIG. 5, the first scanning field region S1 comprises a region in which a material of the imaging structure L is situated. The scanning field S can further comprise, e.g. a second scanning field region S2. The second scanning field region S2 projects beyond the imaging structure L. In FIG. 5, the second scanning field region S2 comprises a region in which no imaging structure L material is situated. For example, the second scanning field region S2 might comprise a region covering a capping layer of the mask. Thus, the second scanning field region S2 may correspond to a clear region of the mask in which, according to the mask design, there should be no radiation absorption. However, as mentioned, a deposition gas might be present in the scanning field S. Consequently, there might be an (inadvertent) electron beam-induced deposition from the deposition gas when the scanning field S is raster-scanned by an electron beam.

As described herein, this may be the case if the correction mark positions are determined within the scope of an electron beam-induced deposition. For example, a mask defect can be repaired by way of an electron beam-induced deposition with at least one deposition gas. Conventionally, the scanning field S of the reference marking M is raster-scanned multiple times for the purpose of correcting the electron beam drift. For example, the deposition gas for repairing the defect can also reach the site of the scanning field (e.g. by way of diffusion). This may also occur if the deposition gas is provided only locally over the defect. For example, the reference markings M are placed as close as possible to the defect, and so the deposition gas usually has a comparatively short diffusion path from the defect to the reference markings. What might also occur is that the deposition gas cannot be limited to the defect from a technical point of view, and so the reference markings might be exposed to the deposition gas as a matter of principle. Thus, foreign material might be deposited in the scanning field.

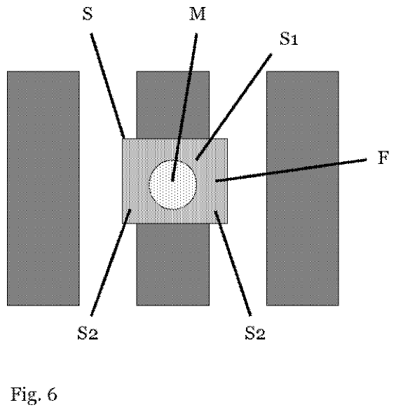

In this respect, FIG. 6 schematically shows a plan view of a foreign material F which was created when the scanning field S was raster-scanned and which can be processed in accordance with a method according to the invention. It is evident that deposited foreign material is situated in the entire scanning field S. It is also identifiable that foreign material F is present both in the first scanning field region S1 and in the second scanning field region S2. The foreign material F was deposited on the imaging structure L in the first scanning field region S1 and next to the imaging structure L (e.g. on the capping layer of the mask) in the second scanning field region S2.

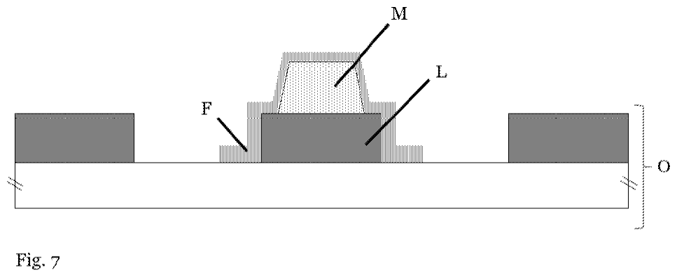

FIG. 7 schematically shows the foreign material F of FIG. 6 in a side view. It is evident in the side view that the foreign material F is firstly deposited on the reference marking M. Further, the foreign material may be present on the plateau of the imaging structure L and on the side walls thereof. It is likewise identifiable that the foreign material F is located next to the imaging structure L (e.g. on the capping layer of the mask). Especially the foreign material F next to the imaging structure L (in the second scanning field region S2) may be problematic for lithography with the mask. This is because this region represents a clear region according to the mask design, in which there should be no radiation absorption (and/or no phase shift). The foreign material F in this region may therefore lead to an optical error.

However, it is also conceivable that the foreign material F causes an optical error on the imaging structure L. For example, the reason for this can be that this foreign material F extends up to the edge (and/or onto the side walls) of the imaging structure (as elucidated in FIG. 7). For example, the foreign material F can thus exert a lateral influence on the imaging structure and e.g. lead to a lateral optical error.

Thus, according to the invention, the foreign material F in the scanning field S can be reduced in terms of volume and/or removed in full.

In another example, it is also conceivable that a foreign material F created by the scanning field is only removed from next to the imaging structure (e.g. only in the second scanning field region S2).

In a further example, it is also conceivable that only the foreign material F next to the imaging structure L is removed in a first step (e.g. foreign material F in the second scanning field region S2). The foreign material F on the imaging structure L and/or on the reference marking M can be removed in a second step (e.g. foreign material F in the first scanning field region S1).

In an example of a method, only foreign material present in the scanning field S can be reduced in terms of volume and/or removed in full.

In another example of a method, the reference marking M and the foreign material Fin the scanning field S can be reduced in terms of volume, with the result that the reference marking M and the foreign material F remain on the mask.

In another example of a method, the reference marking M can be reduced in terms of volume, with the result that the reference marking remains, wherein the foreign material F in the scanning field S is removed from the mask in full (substantially without residue).

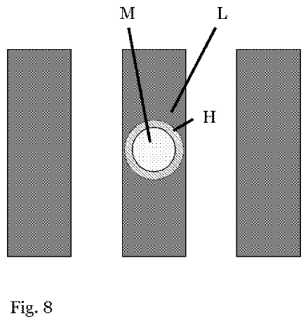

FIG. 8 schematically shows a plan view of a foreign material which is in the form of a halo H present around the reference marking M and which can be processed in accordance with a method according to the invention. As described herein, the halo H might have been created during the electron beam-induced deposition of the reference marking M. For example, electrons may in the process concentrate locally around the reference marking (e.g. as a result of scattered electrons). Thus, an electron beam-induced deposition reaction may likewise arise around the marking, and this may lead to the formation of the halo H.

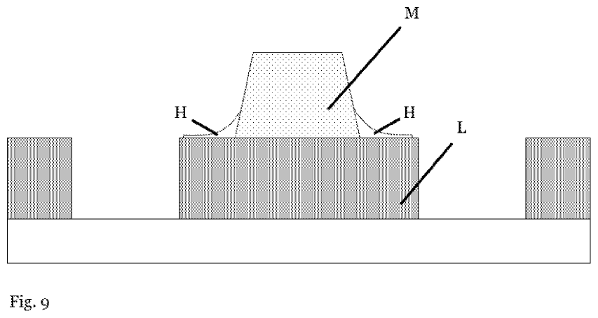

FIG. 9 schematically shows a side view of the halo H of FIG. 8. It is evident that the halo H might have a lower height than the reference marking M. It should be noted that the halo H need not necessarily have a homogeneous layer height (as depicted in FIG. 9). For example, the layer height of the halo H might also, e.g. vary or be irregular. It is also identifiable that the halo might be located in immediate surroundings of the reference marking M. According to the invention, the halo H can be reduced in terms of volume and/or removed.

In an example of a method, it may be the case that the halo H is only reduced in terms of volume (wherein the halo H otherwise remains) and/or is removed in full.

In another example of a method, the reference marking M can be reduced in terms of volume, with the result that the reference marking remains, with the halo H being removed from the mask in full (substantially without residue).

In another example of a method, the reference marking M can be reduced in terms of volume, with the result that the reference marking remains, with the halo H being removed from the mask in full (substantially without residue) and the foreign material F in the scanning field S being able to be reduced in terms of volume and/or removed in full.

In another example of a method, the volume of the reference marking M and of the halo H might be reduced, with the result that the reference marking M and the halo H remain on the mask.

For the sake of completeness, it should be mentioned that the methods described herein need not necessarily be restricted to the aforementioned structure widths and/or structure heights. For instance, the method can also be applied to structure widths greater than 100 nm.

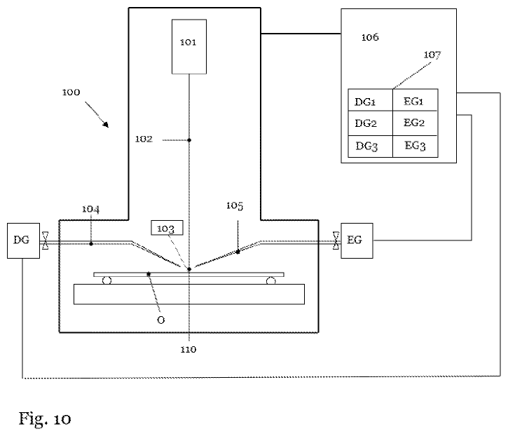

FIG. 10 schematically shows a device 100 according to the invention. The device 100 may comprise a mask repair device which was adapted in accordance with the invention. For example, the device 100 can be designed such that an electron beam-induced etching and/or deposition on a mask O can be performed. The device 100 may comprise, e.g. an electron source 101. The electron source 101 can emit an electron beam 102 which can be used to perform electron beam-induced etching or deposition on a mask O. The means for deflecting, focusing and/or adapting the electron beam are not plotted in FIG. 10. The device 100 can be configured such that the electron beam is able to be incident on a defined point of incidence 103 on the mask O.

Further, the device may provide one or more deposition gases DG on the object O. These can be guided to the object via an appropriate gas line 104. The device can also provide one or more etching gases EG on the object. For example, these can be provided on the object O via an appropriate gas line 105. Further, additive gases can be supplied to the one or more deposition gases DG and/or the one or more etching gases EG. For the sake of simplicity, the containers for the one or more additive gases are not shown in FIG. 10.

Further, the device 100 may comprise a user interface, by means of which an operator can, e.g. operate the device 100 and/or readout data.

Further, the device may comprise a computer unit 106. The computer unit 106 can cause the device 100 to perform one of the methods described herein, based at least in part on an execution of an appropriate computer program.

FIG. 10 also depicts a database 107, which may be comprised, e.g. in the device 100. As described herein, the etching gas for reducing the volume of the reference marking M and/or of the foreign material may be based on a deposition gas used to deposit the reference marking and/or the foreign material. For example, an etching gas can be associated with a deposition gas. Analogously, the etching gas for processing the reference marking and/or the foreign material may be based on the material composition of the reference marking and/or of the foreign material. The database may comprise, e.g. a lookup table, as described herein. In the database, the deposition gas may be associated with a corresponding etching gas, for example. If the intention is to select an etching gas within the scope of the method, then this can be based on the deposition gas used previously when creating the reference marking and/or the foreign material. For example, the database 107 may store the fact that, for the purpose of reducing the volume, a first etching gas EG1 is to be used when a first deposition gas DG1 is used. Accordingly, it may be stored that, for the purpose of reducing the volume, a different second etching gas EG2 is to be used when a second deposition gas DG2 is used, etc. For example, the database 107 may be communicatively coupled to the computer unit 106. Further, the computer unit 106 may also comprise the database 107.

For example, the reference marking may have been created by way of a focused electron beam-induced deposition with a deposition gas DG. As mentioned, the repair of a defect may also comprise an electron beam-induced deposition with a deposition gas DG, which may correspondingly have as a consequence a deposition of the foreign material F (in the scanning field S). In both types of deposition, e.g. one of the following deposition gases DG (or gas mixture) may have been used: Cr(CO)₆, Cr(CO)₆ and NO₂, TEOS, TEOS and NO₂, Mo(CO)₆, Mo(CO)₆ and NO₂. The substances of these deposition gases or gas mixtures may be present in the corresponding deposition material. In an example, the deposition gas DG used to deposit the reference marking and/or the deposition gas DG used for the repair may be stored in the database. On the basis of the database, the appropriate etching gas can then be chosen for the purpose of reducing the volume.

A chromium-based reference marking M or a chromium-based foreign material F can be removed or reduced in terms of volume (e.g. reduced in terms of height) using, e.g. the precursors NOCI and H₂O. Chromium-based reference markings M or chromium-based foreign material F may also be processed or reduced in terms of volume (e.g. reduced in terms of height) using, e.g. XeF₂ and H₂O, or XeF₂ and H₂O and NO₂. In this case, the process with NOCI and H₂O may have a high selectivity when removing the deposited material vis-à-vis damage to the mask material, e.g. vis-à-vis molybdenum silicide (e.g. MoSi and/or MoSi₂), OMOG (Opaque MoSi on Glass), chromeless phase lithography (CPL) and EUV mask materials.

The aforementioned methods are also suitable for removing and/or reducing the height of chromium-based foreign material at a repair site (of a defect) or in its surroundings. As described herein (for the sixth aspect of the invention), it is possible e.g. according to the invention to process foreign material in the surroundings of a repair material. Thus, a chromium-based halo (as foreign material) may, e.g. occur in surroundings of a repair site (or a repair material), and this can be processed in accordance with the methods described herein.

A reference marking and/or a foreign material including TEOS and/or silicon oxide can, e.g. be selectively removed or reduced in terms of volume using the precursors XeF₂ or XeF₂ and H₂O.

The aforementioned methods are also suitable for removing and/or reducing the height of TEOS-based or silicon oxide-based foreign material at a repair site (of a defect) or in its surroundings. As described herein (for the sixth aspect of the invention), it is possible e.g. according to the invention to process foreign material in the surroundings of a repair material. For example, a halo comprising TEOS and/or silicon oxide may also occur, e.g. in surroundings of a repair site (or of a repair material), wherein the halo can be processed in accordance with the methods described herein.

A reference marking and/or a foreign material including molybdenum can be removed or reduced in terms of volume using the precursors XeF₂ and H₂O or H₂O. In this case, the process with H₂O may have a high selectivity when removing the deposited material vis-à-vis damage to the mask material, e.g. vis-à-vis molybdenum silicide (e.g. MoSi and/or MoSi₂), OMOG (Opaque MoSi on Glass), CPL and EUV mask materials.

The aforementioned methods are also suitable for removing and/or reducing the height of molybdenum-based deposition material at a repair site (of a defect) or in its surroundings. As described herein (for the sixth aspect of the invention), it is possible e.g. according to the invention to process foreign material in the surroundings of a repair material. A halo comprising molybdenum may thus also occur in surroundings of a repair site (or of a repair material), wherein the halo can be processed in accordance with the methods described herein.

The invention can further enable an automated, software-based workflow for processing a reference marking and/or a foreign material.

As mentioned, the method may initially comprise a repair of a defect, in which the position of the reference markings is used, e.g. for drift correction.

The quality of the repair can be assessed following the completion of the repair process. For example, this can be implemented by an operator of the device 100. For example, the repair site can be displayed on the user interface for the operator. Further, it is also conceivable that the quality of the repair is implemented by way of an internal and/or external evaluation program. The evaluation program can be installed on, e.g. the device 100. Further, it is also conceivable that repair data are transmitted to the external evaluation program for quality assurance.

If the repair or the quality thereof was assessed as successful, the operator can start automated processing of the reference markings and/or foreign material where necessary, according to any of the methods described herein. For instance, the operator can make an appropriate input on the user interface of the device 100 to this end. It is also conceivable that (in the case of a successful repair) the internal and/or external evaluation program automatically starts the processing of the reference markings and/or of the foreign material, according to any of the methods described herein. In both cases, one of the methods described herein can thus be automatically prepared and started. For the automated execution of the methods described herein, it is possible to resort to, e.g. the database 107, from which it is evident what etching gas is to be used (in view of the deposition gas used).

In some implementations, the computer unit 106 can include one or more computers that include one or more data processors configured to execute one or more programs that include a plurality of instructions according to the principles described above. Each data processor can include one or more processor cores, and each processor core can include logic circuitry for processing data. For example, a data processor can include an arithmetic and logic unit (ALU), a control unit, and various registers. Each data processor can include cache memory. Each data processor can include a system-on-chip (SoC) that includes multiple processor cores, random access memory, graphics processing units, one or more controllers, and one or more communication modules. Each data processor can include millions or billions of transistors.

The methods described in this document can be carried out using one or more computers, which can include one or more data processors for processing data, one or more storage devices for storing data, and/or one or more computer programs including instructions that when executed by the one or more computers cause the one or more computers to carry out the processes. The one or more computers can include one or more input devices, such as a keyboard, a mouse, a touchpad, and/or a voice command input module, and one or more output devices, such as a display, and/or an audio speaker.

In some implementations, the one or more computing devices can include digital electronic circuitry, computer hardware, firmware, software, or any combination of the above. The features related to processing of data can be implemented in a computer program product tangibly embodied in an information carrier, e.g., in a machine-readable storage device, for execution by a programmable processor; and method steps can be performed by a programmable processor executing a program of instructions to perform functions of the described implementations. Alternatively or in addition, the program instructions can be encoded on a propagated signal that is an artificially generated signal, e.g., a machine-generated electrical, optical, or electromagnetic signal, that is generated to encode information for transmission to suitable receiver apparatus for execution by a programmable processor.

A computer program can be written in any form of programming language, including compiled or interpreted languages, and it can be deployed in any form, including as a stand-alone program or as a module, component, subroutine, or other unit suitable for use in a computing environment.

For example, the one or more computers can be configured to be suitable for the execution of a computer program and can include, by way of example, both general and special purpose microprocessors, and any one or more processors of any kind of digital computer. Generally, a processor will receive instructions and data from a read-only storage area or a random access storage area or both. Elements of a computer system include one or more processors for executing instructions and one or more storage area devices for storing instructions and data. Generally, a computer system will also include, or be operatively coupled to receive data from, or transfer data to, or both, one or more machine-readable storage media, such as hard drives, magnetic disks, solid state drives, magneto-optical disks, or optical disks. Machine-readable storage media suitable for embodying computer program instructions and data include various forms of non-volatile storage area, including by way of example, semiconductor storage devices, e.g., EPROM, EEPROM, flash storage devices, and solid state drives; magnetic disks, e.g., internal hard disks or removable disks; magneto-optical disks; and CD-ROM, DVD-ROM, and/or Blu-ray discs.

In some implementations, the processes described above can be implemented using software for execution on one or more mobile computing devices, one or more local computing devices, and/or one or more remote computing devices (which can be, e.g., cloud computing devices). For instance, the software forms procedures in one or more computer programs that execute on one or more programmed or programmable computer systems, either in the mobile computing devices, local computing devices, or remote computing systems (which may be of various architectures such as distributed, client/server, grid, or cloud), each including at least one processor, at least one data storage system (including volatile and non-volatile memory and/or storage elements), at least one wired or wireless input device or port, and at least one wired or wireless output device or port.

In some implementations, the software may be provided on a medium, such as CD-ROM, DVD-ROM, Blu-ray disc, a solid state drive, or a hard drive, readable by a general or special purpose programmable computer or delivered (encoded in a propagated signal) over a network to the computer where it is executed. The functions can be performed on a special purpose computer, or using special-purpose hardware, such as coprocessors. The software can be implemented in a distributed manner in which different parts of the computation specified by the software are performed by different computers. Each such computer program is preferably stored on or downloaded to a storage media or device (e.g., solid state memory or media, or magnetic or optical media) readable by a general or special purpose programmable computer, for configuring and operating the computer when the storage media or device is read by the computer system to perform the procedures described herein. The inventive system can also be considered to be implemented as a computer-readable storage medium, configured with a computer program, where the storage medium so configured causes a computer system to operate in a specific and predefined manner to perform the functions described herein.

The embodiments of the present invention that are described in this specification and the optional or alternative features and properties respectively mentioned in this regard should also be understood to be disclosed in all combinations with one another. In particular, in the present case, the description of a feature comprised by an embodiment-unless explicitly explained to the contrary-should also not be understood such that the feature is essential or indispensable for the function of the embodiment. Other embodiments are within the scope of the following claims.

What is claimed is:

1. A method of processing a lithography object, comprising:
processing, with a particle beam and an etching gas, a marking having been deposited on the object in order to reduce the volume of the marking, wherein the marking remains on the object.

2. The method of claim 1, wherein the volume is reduced such that the processed marking causes no deviation with regards to a predetermined specification during lithography.

3. The method of claim 1, wherein the volume of the marking is reduced by at least 10%.

4. The method of claim 1, wherein the marking is deposited on an imaging structure of the object.

5. The method of claim 4, wherein the volume is reduced such that a height of the processed marking in relation to the imaging structure is smaller than a height of the imaging structure in relation to the object.

6. The method of claim 5, wherein the marking is processed such that the height of the processed marking is at least 10% less than the height of the imaging structure.

7. The method of claim 4, wherein the imaging structure comprises a lateral dimension of no more than 100 nm.

8. The method of claim 4, wherein a lateral dimension of the marking prior to processing corresponds to at least 50% of a lateral dimension of the imaging structure.

9. The method of claim 1, further comprising:
processing a foreign material of the object in surroundings of the marking using the particle beam and the etching gas in order to reduce the volume of the foreign material.

10. The method of claim 9, wherein the foreign material comprises a deposition material which was created when the marking was deposited.

11. The method of claim 9, wherein the foreign material comprises a foreign material around the marking.

12. The method of claim 9, wherein the foreign material comprises a deposition material which was created when the marking was raster-scanned within a scanning field.

13. The method of claim 9, wherein the foreign material is present next to an imaging structure of the object and/or on an imaging structure of the object.

14. The method of claim 1, further comprising:
selecting the etching gas, the etching gas being selected at least in part on the basis of a provided deposition gas used to deposit the marking and/or a foreign material on the object in surroundings of the marking.

15. The method of claim 14, wherein the etching gas comprises a halogen.

16. The method of claim 15, wherein the halogen comprises chlorine if the deposition gas comprises chromium.

17. The method of claim 16, wherein the etching gas further comprises nitrogen and oxygen.

18. The method of claim 16, wherein the etching gas comprises chlorine, nitrogen and oxygen in a compound.

19. The method of claim 15, wherein the halogen comprises fluorine if the deposition gas comprises chromium and/or if the deposition gas comprises silicon and oxygen and/or if the deposition gas comprises molybdenum.

20. The method of claim 19, wherein the etching gas further comprises xenon.

21. The method of claim 20, wherein the etching gas comprises fluorine and xenon in a compound.

22. The method of claim 14, wherein the etching gas includes oxygen if the deposition gas comprises molybdenum.

23. The method of claim 22, wherein the etching gas comprises water.

24. The method of claim 1, wherein the marking and/or the foreign material is further processed using an additive gas which includes oxygen.

25. The method of claim 24, wherein the additive gas comprises water and/or nitrogen dioxide.

26. A computer program comprising instructions for performing a method of claim 1, when they are carried out.

27. An apparatus for processing a lithography object, comprising:
means for processing a marking, which had been deposited on the object, with a particle beam and an etching gas for reducing the volume of the marking such that the marking remains on the object; and
a computer unit which causes the apparatus to perform the method of claim 1, based at least in part on an execution of a computer program comprising instructions for performing the method of claim 1, when they are carried out.
